(19) United States
(12) Patent Application Publication
(10) Pub. No.: US 2013/0027143 A1
(43) Pub. Date: Jan. 31, 2013

(54) ANTIRESONANT FREQUENCY-VARYING COMPLEX RESONANCE CIRCUIT

(71) Applicant: Koichi Hirama, Hiratsuka-Shi (JP)

(72) Inventor: Koichi Hirama, Hiratsuka-Shi (JP)

(73) Assignee: MARCDEVICES CO., LTD., Hiratsuka-shi, Kanagawa (JP)

(21) Appl. No.: 13/577,807

(22) PCT Filed: Feb. 7, 2011
(86) PCT No.: PCT/JP2011/052499

§ 371 Date: Oct. 17, 2012

(30) Foreign Application Priority Data
Feb. 9, 2010 (JP) 2010-026490

(51) Int. Cl. H03B 5/32

(52) U.S. Cl. 331/116 R

(57) ABSTRACT

A complex resonance circuit includes a first current path performing a first phase shift and a first gain control to an AC power signal supplied, at least one second current path performing a second phase shift different in amount from the first phase shift and a second gain control different in amount from the first gain control to the AC power signal, at least two resonant circuits which are provided each on the respective first and second current paths, and have mutually different resonance points or antiresonance points for the AC power signals each passing through the respective first and second current paths and capture the respective AC power signals, and an analog operational circuit for allowing the AC power signals having passed through the first and second current paths to be subjected to addition or subtraction in an analog fashion for output.

### TECHNICAL FIELD

The present invention relates to an antiresonant frequency-varying complex resonance circuit which enables a variable antiresonant frequency range to be flexibly set.

### BACKGROUND ART

For electronic components which utilize the natural resonant frequency of, e.g., piezoelectric oscillators, a method for connecting reactive elements such as capacitors in parallel is well-known as means for varying the zero phase frequency, i.e., the antiresonant frequency thereof; however, the frequency range itself cannot be varied by changing the physical constants such as of the piezoelectric oscillators. As a result, an attempt to make a wide frequency variable range available would result in decrease in output itself.

Disclosed in PTL 1 is a circuit for varying the frequency, which gives a relative minimum power at a power summing point, by controlling the ratio of voltages to be applied to a resonant circuit that includes two series resonant circuits. In this circuit, the frequency range with two series resonant frequencies at the respective ends can be arbitrarily controlled by varying the voltage ratio being applied. However, at the center of the variable frequency range, there occurs an extreme deterioration in the effective resonance quality factor Q which is computed from the frequency range (3 dB bandwidth), in which the effective value of power is twice that at a relative minimum, based on the performance at the relative minimum, that is, the relation between the effective value of power at the relative minimum and the frequency.

Furthermore, the effective Q values at the ends of the variable frequency range suffer, in practice, significant deterioration when compared with the resonance quality factor Q without load on the crystal oscillator.

Means for cancelling the parallel capacitance of the crystal oscillator which restricts the variable frequency range is disclosed in PTL 2; however, the means cannot provide a wide variable frequency range.

Disclosed in NPL1 is an approach which allows an oscillator circuit for outputting one fixed frequency to provide an improved effective resonance quality factor Q as a whole bridge circuit by placing a crystal oscillator on one side of the bridge and selecting arbitrary circuit components on the other sides. However, the frequency cannot be varied over a wide band.

In summary, conventional complex resonance circuits provided only undesirable performances in practice: the operative resonance quality factor Q was greatly varied over the entirety of a wide variable frequency range; and significant deterioration was found in the resonance quality factor Q when compared with the resonance quality factor Q of the employed resonance element itself.

### CITATION LIST

### Patent Literature

PTL 1: International Publication No. 2006/046672
PTL 2: Japanese Patent Kokai No. H8-204451

### Non-Patent Literature

NPL 1: W. R. Sooy, F. L. Vernon, and J. Munushian: “A Microwave Meacham Bridge Oscillator”, Proc. IRE, Vol. 48, No. 7, pp. 1297-1306, July 1960

### SUMMARY OF INVENTION

### Technical Problem

It is an object of the present invention to provide an antiresonant frequency-varying complex resonance circuit which enables a complex resonance circuit with an oscillator, such as a piezoelectric oscillator, having a good resonance quality to achieve a value close to the resonance quality factor Q with the employed resonance element unloaded and set an antiresonant variable frequency range with a high degree of flexibility over a wide frequency range.

### Solution to Problem

To address the aforementioned problems, the antiresonant frequency-varying complex resonance circuit according to the present invention includes: a first current path on which a first phase shift and a first gain control are provided to an AC power signal being supplied; at least one second current path on which a second phase shift and a second gain control are provided to the AC power signal, the second phase shift and the second gain control being different in amounts of shift and control from the first phase shift and the first gain control; at least two resonant circuits which are provided each on the respective first and second current paths, and which have mutually different resonance points or antiresonance points for the AC power signals each passing through the respective first and second current paths and capture the respective AC power signals; and an analog operational circuit for allowing the AC power signals having passed through the first current path and the second current path to be subjected to addition or subtraction in an analog fashion for output.

### Advantageous Effects of Invention

The antiresonant frequency-varying complex resonance circuit of the present invention allows a variable resonance frequency range to be set with a high degree of flexibility without deterioration in effective resonance quality factor Q over a desired variable frequency range.

### BRIEF DESCRIPTION OF DRAWINGS

FIG. 1 is a circuit diagram illustrating an antiresonant frequency-varying complex resonance circuit according to a first embodiment of the present invention.

FIG. 2 is a view illustrating the simulation results of the frequency variation characteristics of an antiresonant frequency-varying complex resonance circuit according to a conventional technique.

FIG. 3 is a view illustrating the simulation results of the frequency variation characteristics of the antiresonant frequency-varying complex resonance circuit according to the first embodiment.

FIG. 4 is a view showing the presence of an optimum value for phase shifts.

FIG. 5 is a block diagram for function analysis of an antiresonant frequency-varying complex resonance circuit of the present invention.

FIG. 6 is an explanatory view illustrating a mechanism for revealing Null frequency.

FIG. 7 is an explanatory view showing the reason why the resonance quality factor Q can be increased.

FIG. 8 is an explanatory view showing the reason why the resonance quality factor Q can be increased.

FIG. 9 is an explanatory view illustrating the reason why the resonance quality factor Q can be increased.

### DESCRIPTION OF EMBODIMENTS

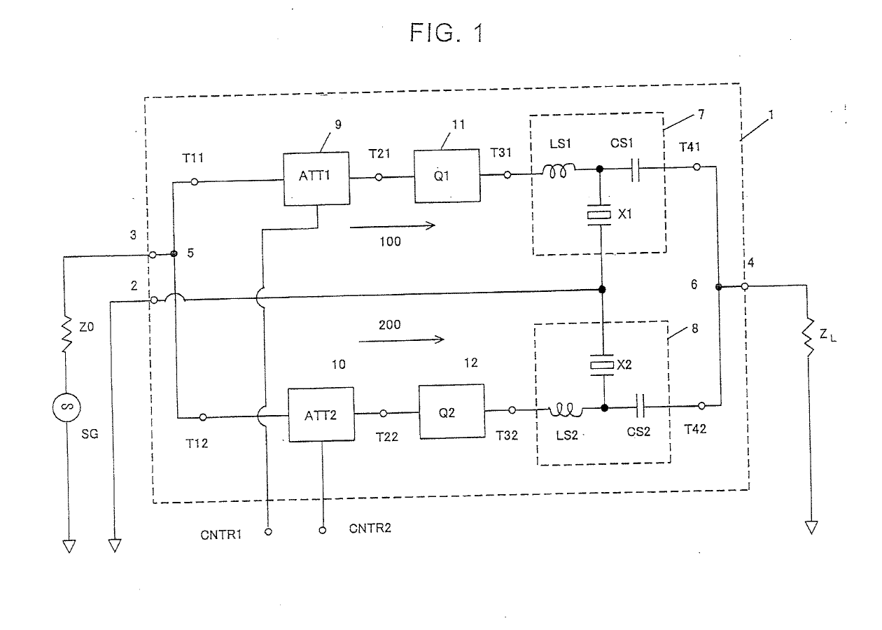

FIG. 1 shows an antiresonant frequency-varying complex resonance circuit according to a first embodiment of the present invention. As shown in FIG. 1, the antiresonant frequency-varying complex resonance circuit 1 includes: a reference terminal 2; an input terminal 3; a first attenuation circuit (attenuator ATT1) and a second attenuation circuit 10 (attenuator ATT2) for attenuating the power level of an input signal at a frequency f, which has been supplied from the input terminal 3 via a power distribution circuit 5 and a terminal T11 or a terminal T12, into mutually different power levels e₁ and e₂, and for supplying each of the signals at the resulting power to a first phase shift circuit 11 or a second phase shift circuit 12 via a terminal T21 or a terminal T22; the first phase shift circuit 11 and the second phase shift circuit 12 for providing mutually different phase shifts θ1 and θ2 to each of the signals at the resulting power supplied from the first attenuation circuit 9 and the second attenuation circuit 10 and for supplying each of the phase-shifted signals to a first resonator circuit 7 or a second resonator circuit 8 via a terminal T31 or a terminal T32; the resonator circuit 7 and the resonator circuit 8 connected via the terminal T31 or the terminal T32 to each of the first phase shift circuit 11 and the second phase shift circuit 12; a power adder circuit 6 connected via a terminal 41 or a terminal 42 to each of the resonator circuit 7 and the resonator circuit 8; and an output terminal 4 connected to the power adder circuit 6. Furthermore, the path from the terminal T11 to the terminal T41 is defined as a first current path 100, while the path from the terminal T12 to the terminal T42 is defined as a second current path 200.

Each component of the antiresonant frequency-varying complex resonance circuit 1 shown in FIG. 1 will be described in more detail. The input terminal 3 of the antiresonant frequency-varying complex resonance circuit 1 of FIG. 1 is connected with a standard signal generator SG which produces an AC power signal, so that an input signal maintained at a constant output at a continuously swept frequency f is applied to the input terminal 3 of the antiresonant frequency-varying complex resonance circuit 1. The input signal is supplied to each of the first attenuation circuit 9 and the second attenuation circuit 10 via the power distribution circuit 5 and the terminal T11 or the terminal T12.

The first attenuation circuit 9 has an input terminal (not shown), an output terminal (not shown), and an external control terminal CNTR1. Control is provided through this external control terminal CNTR1, thereby allowing the first attenuation circuit 9 to vary arbitrarily the ratio of the power level at the input terminal and the power level at the output terminal and then output the signal at the resulting power from the output terminal via the terminal T21 to the first phase shift circuit 11. Note that the input terminal of the first attenuation circuit 9 connects to the terminal T11.

The second attenuation circuit 10 has an input terminal (not shown), an output terminal (not shown), and an external control terminal CNTR2. Control is provided through this external control terminal CNTR2, thereby allowing the second attenuation circuit 10 to vary arbitrarily the ratio of the power level at the input terminal and the power level at output terminal and then output the signal at the resulting power from the output terminal via the terminal T22 to the second phase shift circuit 12. Note that the input terminal of the second attenuation circuit 10 connects to the terminal T12.

The first phase shift circuit 11 has an input terminal (not shown) and an output terminal (not shown). The first phase shift circuit 11 provides the phase shift θ1 to the input signal supplied to the input terminal via the terminal T21, and then outputs the phase-shifted signal from the output terminal via the terminal T31 to the first resonator circuit 7. The phase shift θ1 may be a predetermined fixed value or one to be varied in response to a given signal.

The second phase shift circuit 12 has an input terminal (not shown) and an output terminal (not shown). The second phase shift circuit 12 provides the phase shift θ2 to the input signal supplied to the input terminal via the terminal T22, and then outputs the phase-shifted signal from the output terminal via the terminal T32 to the second resonator circuit 8. The phase shift θ2 may be a predetermined fixed value or one to be varied in response to a given signal.

The first resonator circuit 7 connects to the terminal T31, the terminal T41, and the reference terminal 2, and delivers the output therefrom to the output terminal 4 via the terminal T41 and the power adder circuit 6. The first resonator circuit 7 is configured to have a series circuit of a coil LS1 and a capacitor CS1 interposed between the terminal T31 and the terminal T41, and a crystal oscillator X1 disposed between the intermediate point (connection point) of the series circuit and the reference potential 2.

The second resonator circuit 8 connects to the terminal T32, the terminal T42, and the reference terminal 2, and delivers the output therefrom to the output terminal 4 via the terminal T42 and the power adder circuit 6. The second resonator circuit 8 is configured to have a series circuit of a coil LS2 and a capacitor CS2 interposed between the terminal T32 and the terminal T42, and a crystal oscillator X2 disposed between the intermediate point (connection point) of the series circuit and the reference potential 2.

The input signal applied to the input terminal 3 of the antiresonant frequency-varying complex resonance circuit 1 via these circuits is supplied to each of the first resonator circuit 7 and the second resonator circuit 8. The power levels at that time are as follows. That is, the power levels applied to the first resonator circuit 7 and the second resonator circuit 8 have an absolute voltage value of |e₁| and |e₂| in terms of the respective electromotive forces. Furthermore, the first resonator circuit 7 has a phase shift of θ1 relative to the input signal applied to the input terminal 3, whereas the second resonator circuit 8 has a phase shift of θ2 relative to the input signal applied to the input terminal 3. Furthermore, at this time, the terminal T31 and the terminal T32 are set to have an internal resistance of Z_{S1} and Z_{S2}, respectively.

That is, the first resonator circuit 7 is equivalent to a series circuit in which an equivalent power supply for the absolute value of electromotive force of |e₁| with a phase of φ1 is connected to the internal resistance of a resistance value of zₛ₁, whereas the second resonator circuit 8 is equivalent to a series circuit in which an equivalent power supply for the absolute value of electromotive force of |e₂| with a phase of φ2 is connected to the internal resistance of an resistance value of zₛ₂.

Now, a description will be made to an antiresonant frequency-varying complex resonance circuit (not shown) according to a second embodiment of the present invention. Since the second embodiment has the same circuit structure as that of the first embodiment shown in FIG. 1 except the second current path, only different features will be described below.

In the first embodiment shown in FIG. 1, the second current path 200 includes the second attenuation circuit 10, the second phase shift circuit 12, and the second resonator circuit 8. On the other hand, referring to FIG. 1 for explanation purposes, the second current path 200 of the second embodiment is configured to directly connect between the terminal T12 and the terminal T32 of FIG. 1 without intervention of the second attenuation circuit 10 and the second phase shift circuit 12 of FIG. 1, so that an input signal supplied at a frequency f from the input terminal 3 is relayed to the resonator circuit 8 while maintaining the power level and the phase of the input signal. Note that the resonator circuit 8 of the second embodiment has the same structure as that of the second embodiment of FIG. 1.

Now, the performance of the first embodiment will be explained in two steps using the results of numerical simulations. In the first step, a description will be made to the fact that a method according to a conventional technique without the two phase-shift circuits of the first embodiment causes significant deterioration in resonance quality factor Q at the center of a variable frequency range. In the second step, a description will be made to the fact that a phase shift made according to the present invention can provide a significantly improved resonance quality factor Q at the center.

The simulation in the first step was performed at a center frequency of 10 MHz in a variable frequency range of 4000 ppm (from 9980 kHz to 10020 kHz). For this simulation, the two circuits, the resonator circuit 7 and the resonator circuit 8, were given the equivalent circuit constants as shown in Table 1.

TABLE 1

| FIRST RESONATOR CIRCUIT | SECOND RESONATOR CIRCUIT |
|---|---|
| f1 = 9980 kHz | f2 = 10020 kHz |
| L1 = 25.306 mH | L2 = 25.745 mH |
| C1 = 10.04976 fF | C2 = 9.799681 fF |
| R1 = 10.13Ω | R2 = 11.311Ω |
| C01 = 3.619 pF | C02 = 3.8237 pF |
| LS1 = 21.392 μH | LS2 = 21.392 μH |
| CS1 = 8.200 pF | CS2 = 8.17 pF |
| Z_{S1} = 34.68Ω | Z_{S2} = 33.85Ω |

zₗ = 50Ω

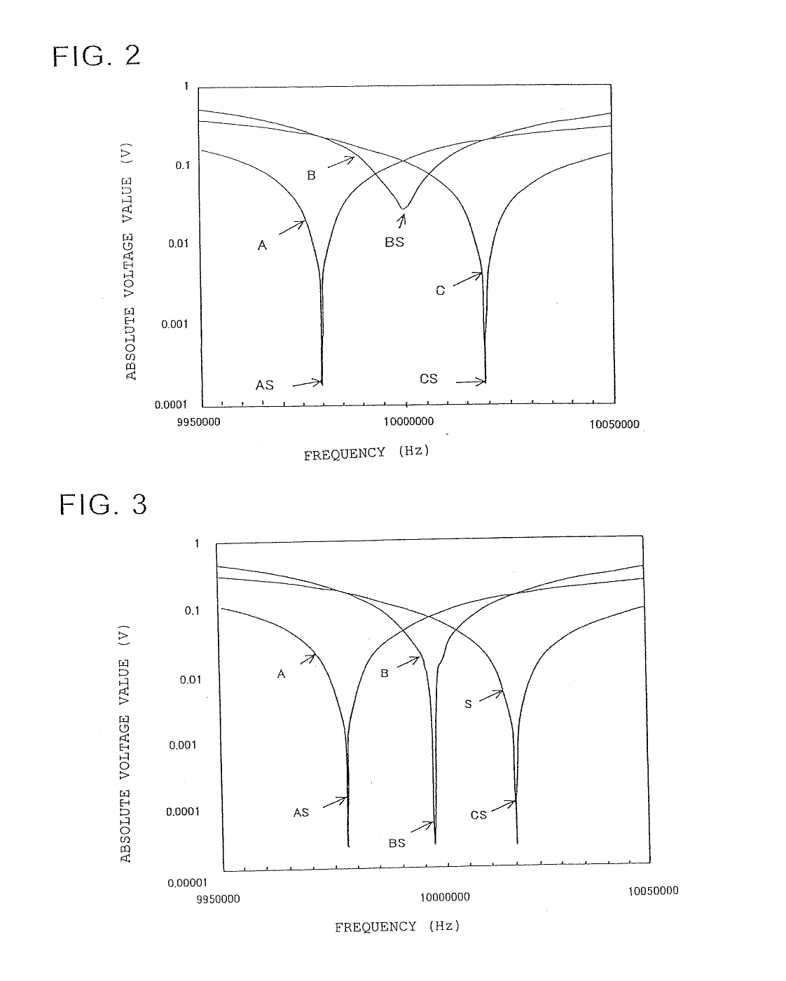

In FIG. 2, the horizontal axis represents the frequency (Hz), and the vertical axis represents the absolute voltage value (V) established across the ends of a load resistance z₁. In this simulation, the method according to the conventional technique without the two phase-shift circuits of the first embodiment was simulated by making zero both the phase shifts θ1 and θ2 of the phase shift circuit 11 and the phase shift circuit 12 shown in FIG. 1.

The antiresonant frequency-varying complex resonance circuit 1 which includes the first resonator circuit 7 and the second resonator circuit 8 having the equivalent constants shown in Table 1 is configured to vary the ratio of the voltage e₁ applied to the first resonator circuit 7 and the voltage e₂ applied to the second resonator circuit 8. This allows the frequency (hereinafter referred to as the Null frequency and denoted by the frequency fnull or fnull) which gives the minimum absolute value of the voltage established across the ends of the load resistance z₁ connected to the output terminal 4 to be arbitrarily varied between the respective resonance frequencies f1 and f2 of the crystal oscillators X1 and X2 included in the first resonator circuit 7 and the second resonator circuit 8. The three curves of FIG. 2, curve A, curve B, and curve C, were obtained by allowing the voltage e₁ applied to the first resonator circuit 7 and the voltage e₂ applied to the second resonator circuit 8 to be set to 1 V (1 volt) and 0 V (0 volt) for the curve A, 1 V and 1 V for the curve B, and 0 V and 1 V for the curve C, respectively. The three curves have the respective relative minima AS, BS, and CS. It was found that the relative minimum BS located near the center frequency is extraordinarily greater than the other two, i.e., the relative minimum AS and relative minimum CS, which shows at first glance that the resonance quality factor Q thereof has extraordinarily deteriorated.

Now, the simulation in the second step shown in FIG. 3 was performed by setting the phase shifts θ1 and θ2 of the first phase shift circuit 11 and the second phase shift circuit 12 shown in FIG. 1 to +7° and −7°, respectively. Note that in FIG. 3, as in FIG. 2, the horizontal axis represents the frequency and the vertical axis represents the absolute value of the voltage established across the ends of the load resistance z₁. The relative minimum BS at the center shows the phenomenon of an extraordinarily low voltage (hereinafter referred to as the Null phenomenon). Accordingly, in FIG. 3, the vertical axis represents plotted values which are smaller than those in FIG. 2 by an order of magnitude. Furthermore, the resonance quality factor Q of the resonance curve at the center shows no noticeable deterioration when compared with the other two, i.e., the resonance curve A and resonance curve C. Furthermore, such a reduced deterioration provides the effect that deterioration is reduced over the entire variable frequency range even when the two applied voltages are varied in a wide range to thereby vary the Null frequency over the entire variable frequency range.

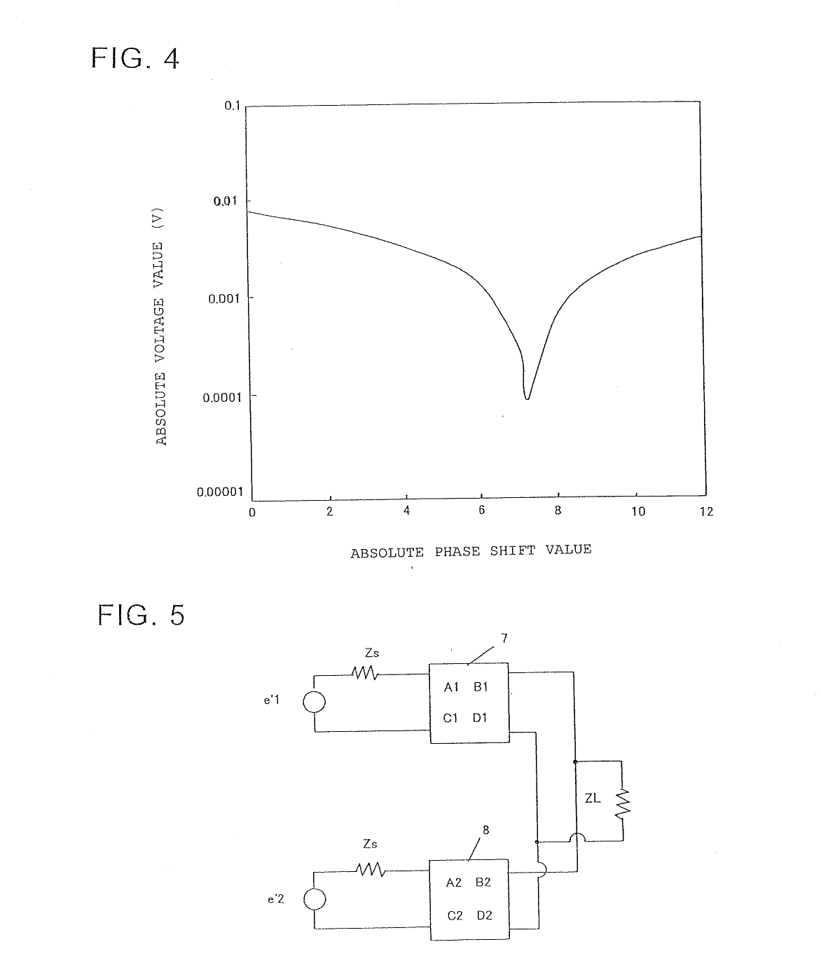

Now, referring to FIG. 4, a description will be made to the fact that the absolute values of phase shift have an optimum value. FIG. 4 is a graph showing variations in the absolute voltage value at the relative minimum BS of FIG. 3 when the absolute value of a phase shift (i.e., x°) is varied where the phase shift circuit 11 and the phase shift circuit 12 shown in FIG. 1 have phase shifts θ1 and θ2 of +x° and −x°, respectively. In FIG. 4, the horizontal axis represents the absolute value of a phase shift, and the vertical axis represents the absolute value of a voltage established across the ends of the load resistance z₁.

From FIG. 4, the absolute value of a phase shift of 0° on the horizontal axis corresponds to no phase shift, that is, to the case of the conventional technique with the two circuits of FIG. 1, i.e., the phase shift circuit 11 and the phase shift circuit 12 eliminated. On the other hand, there is a drop near the absolute value of a phase shift of 7° on the horizontal axis. The value at the drop is smaller by about two orders of magnitude than the absolute value of a phase shift of 0°. This means that the resonance quality factor Q of the antiresonant frequency-varying complex resonance circuit 1 has been extraordinarily improved. The absolute value of a phase shift of 7° was an only optimum point in 360°.

In the second embodiment, as in the first embodiment, the Null frequency and the resonance quality factor Q were variable depending on the first phase shift of the first phase shift circuit 11 and the voltage variation of the first attenuation circuit 9 on the first current path.

Now, the operational principle of the first and second embodiments will be explained with reference to FIGS. 5 to 9. FIG. 5 shows the operational principle of the antiresonant frequency-varying complex resonance circuit 1 of the first embodiment shown in FIG. 1 and the antiresonant frequency-varying complex resonance circuit of the second embodiment in a more generalized form with only those portions extracted therefrom that relate to the operational principle. That is, the input terminal of the first resonator circuit 7 is connected with a series circuit of an equivalent power supply for the absolute value of electromotive force of |e₁| with a phase of θ1 and an internal resistance of an resistance value of zₛ₁, while the input terminal of the second resonator circuit 8 is connected with a series circuit of an equivalent power supply for the absolute value of electromotive force of |e₂| with a phase of θ2 and an internal resistance of a resistance value of zₛ₂. Furthermore, the output terminals of the first resonator circuit 7 and the second resonator circuit 8 are connected with the load resistance z₁.

This is constructed in FIG. 5 and expressed as follows: the first power supply for electromotive force e₁′ with an internal resistance of zₛ, the second power supply for electromotive force e₂′ with an internal resistance of zₛ, the first resonator circuit 7 with the input terminal connected to the first power supply, and the second resonator circuit 8 with the input terminal connected to the second power supply are constructed so that the output terminal of the first resonator circuit 7 and the output terminal of the second resonator circuit 8 are each connected to the load resistance z₁. In FIG. 5, the reference terminal 2 is eliminated.

Now, in FIG. 5, the characteristics of the first resonator circuit 7 are expressed by a subordinate matrix with elements a1, b1, c1, and d1, and the characteristics of the second resonator circuit 8 are expressed by a subordinate matrix with elements a2, b2, c2, and d2. In the setting of the parameters mentioned above, the internal resistances zₛ₁ and zₛ₂ of the two power supplies are set to be equal to zₛ: such a setting by slightly changing the value of the matrix elements would not lead to the loss of generality.

Next, the current i_{z1} flowing through the load resistance z₁ is expressed by the equation below. The numerals in the suffixes “1” and “2” correspond to the first resonator circuit 7 and the second resonator circuit 8, respectively.

$${i}_{zl} {z}_{l} = \frac{\frac{{e}_{1}^{′}}{{s}_{1}^{′}} {k}_{2} + \frac{{e}_{2}^{′}}{{s}_{2}^{′}} {k}_{1}}{{k}_{1} + {k}_{2} - {k}_{1} {k}_{2}} \qquad ( 1 )$$

The left-hand side of Equation (1) is the product of the load resistance z₁ of FIG. 5 and the current i_{z1} flowing therethrough. The quantities k₁ and k₂ on the right-hand side have a slight imaginary part, and the absolute values thereof are generally close to one and dimensionless. These quantities are expressed by the equation below.

$${k}_{i} = 1 - \frac{{a}_{i}^{′} - {c}_{i}^{′}}{{s}_{i}^{′}} \qquad ( 2 )$$

Here, ai′, bi′, ci′, and di′ are associated with ai, bi, ci, and di of the subordinate matrix of the resonator circuit in the relation expressed by the equation below, where suffix “i” takes values 1 and 2 corresponding to the first resonator circuit 7 and the second resonator circuit 8, respectively. That is, “i=1” corresponds to the first resonator circuit 7 and “i=2” corresponds to the second resonator circuit 8.

$$\begin{matrix}{a}_{i}^{′} = {a}_{i} & ( 3 a ) \\ {b}_{i}^{′} = {b}_{i} \frac{1}{{z}_{l}} & ( 3 b ) \\ {c}_{i}^{′} = {c}_{i} {z}_{s} & ( 3 c ) \\ {d}_{i}^{′} = {d}_{i} \frac{{z}_{s}}{{z}_{l}} & ( 3 d )\end{matrix}$$

Furthermore, to facilitate the deformation of mathematical expressions, sᵢ′ is obtained by multiplying the operational attenuation sᵢ by z₁/(zₛ+z₁) and is referred to as the deformed operational attenuation, as is defined by the equation below

sᵢ′=aᵢ′+bᵢ′+cᵢ′+dᵢ′ (4)

Next, discussion will be focused on an aspect of the present invention that assuming the operational attenuation of the impedance characteristics of each resonator circuit being substantially symmetric with respect to the resonance frequency, the two dimensionless quantities k₁ and k₂ expressed by Equation (2) slightly have an imaginary part in addition to a real part and are substantially complex conjugate with each other at the center of the variable frequency range.

In this context, the present invention provides a phase difference θ1 and a phase difference θ2 to the two power supplies e₁′ and e₂′ as shown in the equations below. That is,

e₁′=|e₁′|e^{jθ1} (5a)

e₂′=|e₂′|e^{jθ2} (5b)

where |e₁′| and |e₂′| are the absolute voltage values of two electromotive forces e₁′ and e₂′, respectively. Substituting Equations (5a) and (5b) into Equation (1) gives the equation below.

$${i}_{zl} {z}_{l} = \frac{\frac{\vert {e}_{1}^{′} \vert}{{s}_{1}^{′}} {e}^{j θ 1} {k}_{2} + \frac{\vert {e}_{2}^{′} \vert}{{s}_{2}^{′}} {e}^{jθ 2} {k}_{1}}{{k}_{1} + {k}_{2} - {k}_{1} {k}_{2}} \qquad ( 6 )$$

The equation (6) derived above is stringent and holds true for resonator circuits in any forms. According to the findings of the present invention on the two terms e^{jθ1}k₂ and e^{jθ2}k₁ included in the numerator of Equation (6), these two quantities can be made substantially close to a real number at the geometric average frequency, that is, at the center of the variable frequency range. For this purpose, θ1 and θ2 must be selected to be near the setting that they are opposite in sign but equal in the absolute value thereof to each other; this was confirmed from the simulation results.

That is, the two dimensionless quantities k₁ and k₂ expressed by Equation (2) have an absolute value substantially equal to unity with a small loss angle, and can be approximated to a complex conjugate with each other. Thus, Equation (6) can be further simplified into the equation below.

$${i}_{zl} {z}_{l} ≅ \sqrt{\vert {e}_{1}^{′} \vert \vert {e}_{2}^{′} \vert} ( \frac{1}{{s}_{1}^{′}} \sqrt{\frac{\vert {e}_{1}^{′} \vert}{\vert {e}_{2}^{′} \vert}} + \frac{1}{{s}_{2}^{′}} \sqrt{\frac{\vert {e}_{2}^{′} \vert}{\vert {e}_{1}^{′} \vert}} ) \qquad ( 7 )$$

Equation (7) means that the ratio of the two absolute values of electromotive forces |e₁′| and |e₂′| can be varied to cancel the susceptance component of the series arm impedance of the two resonant circuits, the components being included in the deformed operational attenuations s₁′ and s₂′, thereby allowing for varying the frequency fnull which gives the minimum absolute voltage value of a voltage established across the load resistance z₁ between the two series resonant frequencies.

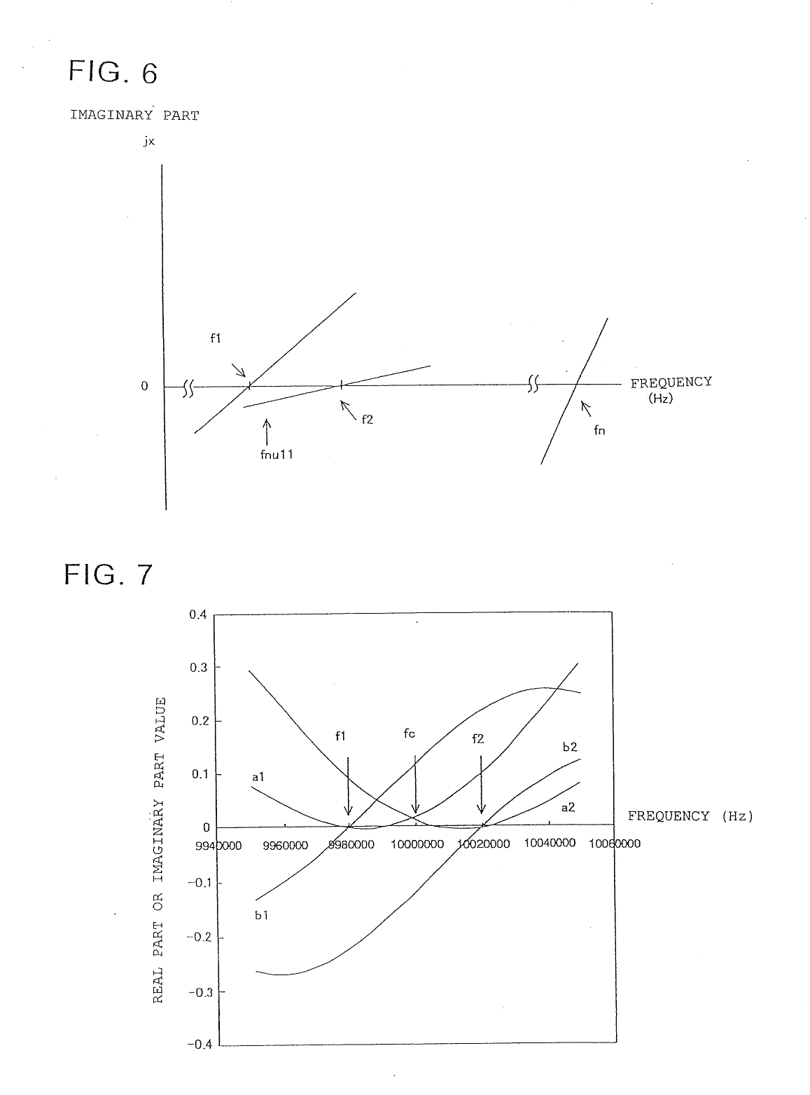

FIG. 6 is a conceptual view of Equation (7). The horizontal axis represents the frequency, and the vertical axis represents the imaginary part on the left-hand side of Equation (7) with the respective susceptance components of the first resonator circuit 7 and the second resonator circuit 8 separately illustrated. In FIG. 6, since the slope of the respective straight lines is proportional to the absolute value of the respective applied voltages |e₁| and |e₂|, it can be seen that varying the ratio of the applied voltages causes the frequency fnull for cancelling out two adjacent susceptance components to be revealed.

Now, the first embodiment shown in FIG. 1 will be more specifically described. The deformed operational attenuation of the first resonator circuit 7 is expressed by the equation below at the only one frequency which has been so set as to draw the effects of only the series arm by removing the influence of the parallel capacitance C01 of the crystal oscillator X1 from the value of the coil LS1 and the capacitor CS1 which constitute the first resonator circuit 7. The equation below also holds true for the second resonator circuit 8. In the equation, suffix “i” denotes the first resonator circuit 7 for “1” and the second resonator circuit 8 for “2.”

$${s}_{i}^{′} = 1 + \frac{{z}_{si} + {r}_{si}}{{z}_{l}} + ( 1 + \frac{ω {l}_{si}}{{z}_{si} + {r}_{si}} \frac{1}{ω {c}_{si} {z}_{l}} ) \frac{{z}_{l}}{{z}_{qsi}} \qquad ( 8 )$$

In the equation, Z_{qsi} is the impedance of the series arm of the crystal oscillator Xi. To be more precise, Equation (8) holds true at one frequency; however, the equation also substantially holds true over a comparatively wide frequency range so as to represent, with a good degree of approximation, the behavior of the antiresonant frequency-varying complex resonance circuit 1. Substituting Equation (8) into Equation (7) gives the approximate expression below.

$${i}_{zl} {z}_{l} ≅ \sqrt{\vert {e}_{1}^{′} \vert \vert {e}_{2}^{′} \vert} ( {k}_{qsi} \frac{{z}_{qsi}}{{z}_{l}} \sqrt{\frac{\vert {e}_{1}^{′} \vert}{\vert {e}_{2}^{′} \vert}} + {k}_{qsi} \frac{{z}_{qsi}}{{z}_{l}} \sqrt{\frac{\vert {e}_{2}^{′} \vert}{\vert {e}_{1}^{′} \vert}} ) \qquad ( 9 )$$

Here, k_{qsi} can be expressed by the equation below.

$$\frac{1}{{k}_{qsi}} = \frac{{l}_{si}}{{c}_{si}} \frac{1}{( {z}_{si} + {r}_{si} ) {z}_{l}} \qquad ( 10 )$$

Since Z_{qsi} in Equation (9) is the impedance of the series arm of the crystal oscillator, the effects of the resistor component thereof are so insignificant as to be negligible. This allows for making a good approximation that the reactance component thereof varies linearly with distance from the series resonant frequency of each crystal oscillator. In this case, as shown in FIG. 6, current i_{z1} in Equation (9) means that the ratio of the two absolute values of electromotive force |e₁′| and |e₂′| can be varied, thereby allowing for varying the frequency fnull at the minimum point thereof. This has been confirmed in the simulation results of FIGS. 2 and 3.

Now, a description will be made to an object of the present invention or the reason why the resonance quality factor Q can be increase. In the first step, the case with no phase shift circuit will be described in relation to the frequency at which the resonance quality factor Q significantly deteriorates, i.e., one frequency fc (10 MHz) at the center of the variable frequency range. Furthermore, in the second step, the case with the aforementioned phase shift circuit will be described in relation to a frequency at which the resonance quality factor Q significantly deteriorates, i.e., one frequency fc (10 MHz) at the center of the variable frequency range. Furthermore, in the third step, a description will be made to the fact that this effect will also be sustained not only at the one frequency but also in a wide frequency range, i.e., even when the entire variable frequency range is swept from the center frequency.

To begin with, the first step will be explained with reference to FIG. 7. FIG. 7 shows the real parts a1 and a2 and the imaginary parts b1 and b2 of the coefficients by which |e₁′| and |e₂′| in Equation (6) are multiplied. The horizontal axis represents the frequency, while the vertical axis represents the value of each part. The imaginary parts b1 and b2 correspond to the two susceptance components which are zero at f1 and f2 in FIG. 6. Since both a curve b1 and a curve b2 have the same slope, the positive and negative susceptance components cancel out each other when the two applied absolute voltage values of |e₁′| and |e₂′| are equal to each other, thereby causing the curve b1 and the curve b2 to take a very low value at the center fc in the variable frequency range. That is, the null phenomenon occurs for the susceptance component.

On the other hand, attention has to be focused on the fact that both the curves a1 and a2 representing the real parts take a very high positive value at the center fc of the variable frequency range. This value is a causal component of loss, and thus may cause a significant deterioration in the resonance quality factor Q due to a high-loss component in the vicinity of the center fc when the frequency is varied. In practice, this corresponds to the fact that the minimum point BS on the curve. B in FIG. 2 exhibits a significant deterioration as compared with the other two minimum points AS and CS. Furthermore, it should be pointed out that the values of the real parts at the frequency f1 or f2 take on a sufficiently low value.

The second step will now be explained. What interests us is the behavior of the curve a1 and the curve a2 which represent the real part. Consider that the phase shift θ1 of the phase shift circuit 11 and the phase shift θ2 of the phase shift circuit 12 in FIG. 1 are each controlled.

On the curve a1, it is possible to set, to zero, the value of the real part at the center fc of the horizontal axis frequency while maintaining the value of the real part at zero at the frequency f1. That is, since the curve a1 can be rotated in the clockwise direction in response to the phase shift θ1, the value of the real part at the frequency f1 can be controlled to zero and the other intersection with the horizontal axis can be set at the center fc of the horizontal axis frequency. In the same manner, rotating the curve a2 in the counterclockwise direction makes it possible to set, to zero, the value of the real part at the center fc of the horizontal axis frequency.

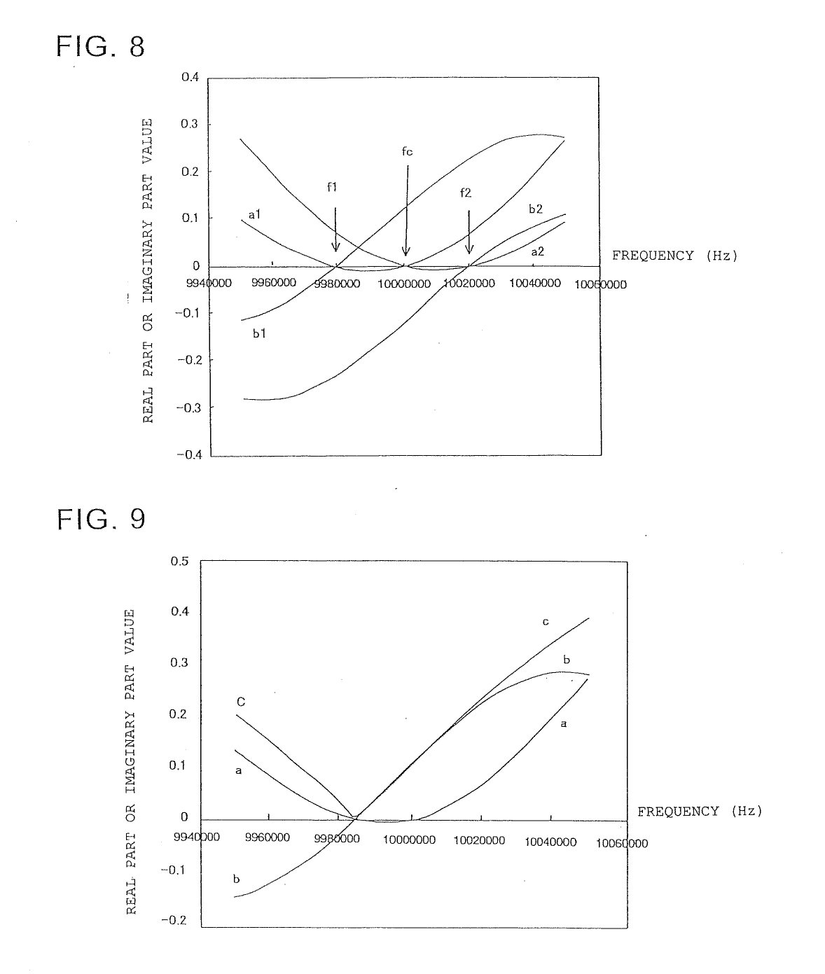

Based on these settings, calculating the phase shifts θ1 and θ2 when typical constants are set from the circuit constants in Table 1 gives 8.5° and −5.5°, respectively. This is shown in FIG. 8. Note that in FIG. 8, the horizontal axis represents the frequency and the vertical axis represents the value of each part. On both the curve a1 and the curve a2, the real part is zero at the center fc of the horizontal axis frequency. Accordingly, the resonance quality factor Q is significantly improved at this frequency. This corresponds to the fact that the minimum point BS of the simulation result curve B in FIG. 3 has dropped to a sufficiently low value.

In other words, the presence of such a phenomenon that the frequency at which the total value of susceptance components is zero substantially coincides with the frequency at which the total value of real parts is zero can be said to have been found.

In the third step, it will be explained that even when the frequency is varied, such a condition that is hardly affected by the real part can be maintained.

To vary the frequency, the ratio of |e₁′| and |e₂′|, that is, the voltage ratio is varied to change the composition ratio of the curve b1 and the curve b2, thereby changing the sum of the amounts of these two compositions, i.e., the frequency fnull at which the total susceptance exhibits zero. When the composition ratio is varied, the sum of the amounts of the two compositions from the curve a1 and the curve a2 should be inevitably maintained at sufficiently small one. This condition is met by the curve a1 and the curve a2. That is, the curve a1 and the curve a2 have mutually different signs, and the absolute value of a positive value is “appropriately greater than” the absolute value of a negative value.

For example, since the value of a1 and the value of a2 have different signs at frequencies lower than the center frequency, the total value of the two is less than the respective absolute values. That is, the value of a2 may be greater than the absolute value of a1, so that the absolute value of one of the applied voltages |e₂| should be reduced in an attempt to decrease fnull to be lower than the center frequency. In this case, the value of a2 is decreased in proportion thereto, causing the total value of real part to be further reduced. That is, use is made of the phenomenon of reducing the absolute value of the real part that would cause loss. This means that even when the frequency is varied, the real part that would cause deterioration in the resonance quality factor Q can be maintained at a small value at all times.

To promote the intuitive understanding of the discussions above, more quantitative explanations will be given below. FIG. 8 has six features to be mentioned as follows. First, there is a substantially equal frequency separation between the frequency fc and the frequency f1 and between the frequency fc and the frequency f2. Note that in the first embodiment, the frequency separations are equal to 20 kHz. Secondly, the curve a1 representative of the real part intersects the horizontal axis at the frequency f1 and at the center frequency fc, and exhibits a second-order curve with a substantially positive second-order coefficient between the frequencies f1 and f2. Thirdly, the curve b1 representative of the imaginary part intersects the horizontal axis at the frequency f1 and exhibits a first-order curve (straight line) which is badly approximated on the side of the frequency f2, but has a substantially positive first-order coefficient between the frequencies f1 and f2. Fourthly, the curve a2 representative of the real part intersects the horizontal axis at the frequency f2 and at the center frequency fc and exhibits a second-order curve which has a substantially positive second-order coefficient between the frequencies f1 and f2. Fifthly, the curve b2 representative of the imaginary part intersects the horizontal axis at the frequency f2 and exhibits a first-order curve (straight line) which is badly approximated on the side of the frequency f1, but has a substantially positive first-order coefficient between the frequencies f1 and f2. Sixthly, the ratio of the second-order coefficient of the curve a1 and the first-order coefficient of the curve b1 (referred to as the coefficient ratio 1) and the ratio of the second-order coefficient of the curve a2 and the first-order coefficient of the curve b2 (referred to as the coefficient ratio 2) exhibit substantially the same value.

To vary the frequency under these situations, the ratio of |e₁′| and |e₂′|, that is, the voltage ratio can be varied to change the composition ratio of the curve b1 and the curve b2, thereby providing the sum of the amounts of the two compositions, i.e., the frequency fnull in the vicinity of which the total susceptance exhibits zero. The results of a mathematical analysis show that the sum of the amounts of the two real part compositions always exhibits substantially zero at all the varied frequencies fnull. In practice, the results of the mathematical analysis below show that the real part exhibits zero not substantially but perfectly in the ideal case for the aforementioned list of six items or the features of the four curves in FIG. 8.

First, for the mathematical analysis not to lose generality, a normalized frequency F is employed for the frequency f of the horizontal axis. Furthermore, the frequency f and the normalized frequency F are related to each other as follows. That is, f1, fc, and f2 are associated with −1, 0, and +1, respectively. Expressing the real part shown in FIG. 8 on the basis of the normalized frequency F, the second-order curve a1 intersects at normalized frequencies −1 and 0 with the second-order coefficient a₂₁ (the first suffix represents “2” as in the second-order coefficient, and the second suffix represents 1 and 2 for the first resonator circuit 7 and the second resonator circuit 8, respectively), while the second-order curve a2 intersects at normalized frequencies 0 and +1 with the second-order coefficient a₂₂. Assuming as described above, the real part on the left-hand side of Equation (6) that causes loss can be expressed by the equation below.

$$Re ( {i}_{zl} {z}_{l} ) = ( \vert {e}_{1}^{′} \vert {a}_{21} + \vert {e}_{2}^{′} \vert {a}_{22} ) \{ F + \frac{\vert {e}_{1}^{′} \vert {a}_{21} - \vert {e}_{2}^{′} \vert {a}_{22}}{\vert {e}_{1}^{′} \vert {a}_{21} + \vert {e}_{2}^{′} \vert {a}_{22}} \} F \qquad ( 11 )$$

Equation (11) is a second-order function for the normalized frequency F, so that Equation (11) exhibits zero at two points: the first point (the normalized frequency F1) at which the normalized frequency F is zero and the second point (the normalized frequency F2) at which the terms within { } of Equation (11) exhibit zero. The second point depends on the two applied absolute voltage values |e₁′| and |e₂′|.

Now, the frequency equation which gives an antiresonant frequency will be determined. The slopes of the first-order curve b1 and the first-order curve b2 of the two imaginary parts in FIG. 8 are proportional to the two second-order coefficients a₂₁ and a₂₂ that are associated with the two second-order curve a1 and second-order curve a2, respectively. Furthermore, focusing on the fact of having the same proportional coefficient (the mutually equal coefficient ratio 1 and coefficient ratio 2), the relation between the normalized frequency Fₐᵣ (suffix “ar” stands for anti-resonance in the antiresonant frequency) at which the imaginary part (the susceptance component) of Equation (6) exhibits zero and the two applied absolute values of |e₁′| and |e₂′|, that is, the frequency equation is expressed by the equation below.

$${F}_{ar} = - \frac{\vert {e}_{1}^{′} \vert {a}_{21} - \vert {e}_{2}^{′} \vert {a}_{22}}{\vert {e}_{1}^{′} \vert {a}_{21} + \vert {e}_{2}^{′} \vert {a}_{22}} \qquad ( 12 )$$

Equation (12) does not reveal explicitly the slopes of the two straight lines b1 and b2 of FIG. 8, but so does implicitly. The reason for that is because of the assumption that the slopes of the two straight lines b1 and b2 are proportional to the corresponding second-order coefficients a₂₁ and a₂₂, respectively.

Now, what interests us is what value is taken by the value of the real part that gives the loss expressed by Equation (11) at the normalized frequency Fₐᵣ at which the reactance component expressed by Equation (12) exhibits zero. Accordingly, the frequency equation, or Equation (12), is substituted into Equation (11) representative of the loss component.

The result of this substitution showed that the value of { } on the right-hand side of Equation (11) took on zero. This is because substituting Fₐᵣ determined by Equation (12) into F in { } of Equation (11) will make the entire { } of Equation (11) zero. Accordingly, at any normalized anti-frequency Fₐᵣ, the loss given by Equation (11) is always zero. That is, this means that when the normalized anti-frequency Fₐᵣ is varied by changing the ratio of the two applied absolute values |e₁′| and |e₂′| under the idealized conditions, the loss is zero, or in other words, the resonance quality factor Q exhibits “infinity” over the entire variable range from −1 (f1) to +1 (f2). In this case, a real frequency f or fₐᵣ which corresponds to Fₐᵣ at which the susceptance component exhibits zero coincides perfectly with fnull. Furthermore, any loss component included in a series or parallel resonant circuit which constitutes the resonator circuit would not hinder the achievement of the resonance quality factor Q at which this extreme “infinity” is exhibited.

Now, with reference to FIG. 9, a description will be made to the fact that a condition close to an ideal one can be achieved even in a not ideal but actual case. The horizontal and vertical axes are the same as those of FIG. 8. FIG. 9 shows the case where the ratio of |e₁′| and |e₂′| is set to 1:0.125 to vary the frequency. The two coefficients by which the two absolute voltage values are multiplied come from the values in FIG. 8.

As shown in FIG. 9, the frequency at which the total value of real part takes on zero on the curve “a” representative of the total value of real part substantially coincides with the frequency at which the total value of imaginary part takes on zero on the curve b indicative of the total value of imaginary part. As a result, the minimum point (null point) of the absolute value curve “c” computed from the two curves takes on a sufficiently small value. This can show that a good condition of the resonance quality factor Q is maintained always when the frequency is varied. The minimum point of the absolute value curve “c” is very small, and thus the same as the shape shown in FIG. 2 or FIG. 3 when the vertical axis is represented by a logarithmic scale.

The causal requirements which reveal the effects of the improvements described above are the phase shifts θ1 and θ2 of the first phase shift circuit 11 and the second phase shift circuit 12. However, when a more moderate performance is allowed for a desired resonance quality factor Q, the total of the two phase-shifts may also be applied to one of the electromotive forces. That is, only one phase shift circuit may suffice. Conversely, when a high resonance quality factor Q is required over a variable frequency range, ganged control can be provided in association with a control signal CNTR for varying the frequency. That is, the phase shift circuit may be provided with an external control terminal to provide fine control to the phase shifts θ1 and θ2. Furthermore, for example, ganged control can be provided to the series capacitance values of the resonator circuits (CS1 and CS2) or to internal resistances Zₛ₁ and Zₛ₂ from the terminal T31 and the terminal T32 toward the input terminal (from the input terminal 3 to the phase shift circuit), thereby allowing for increasing the resonance quality factor Q to an ultimate level.

Some modified embodiments will be listed below.

The attenuation circuit 9, the phase shift circuit 11, and the resonator circuit 7 can be disposed in an arbitrary order between the input terminal 3 and the output terminal 4, and the performance of the present invention does not depend on that order. The performance of the present invention does not depend on the order of the coil LS1 and the capacitor CS1 which constitute the resonator circuit. Furthermore, the resonator circuit can be made up of only a crystal oscillator, or alternatively of a series circuit which is made up of a resistor and a coil and which is connected in parallel with a capacitor. The phase shift circuit may be implemented by employing: a combined circuit of a resistor and a capacitor; a combined circuit of a resistor and an inductive element; a combined circuit of a capacitor and an inductive element; or a delay circuit. Any attenuation circuit may also be an amplification factor variable (gain controllable) amplifier circuit. To employ, as the power adder circuit 6, a reversed-phase adder circuit like an operational amplifier with differential inputs, a differential output distribution circuit like a push-pull output one with differential output terminals can be employed as the power distribution circuit 5. An inductive element like a coil can be represented equivalently by an active circuit and a resistor. As shown in FIG. 6, the variable frequency range can be increased by increasing the number of the arms between the input terminal 3 and the output terminal 4 including the resonator circuit. It is also possible to improve the sharpness of the frequency selection characteristics of the entire antiresonant frequency-varying complex resonance circuit by a subordinate connection of an antiresonant frequency-varying complex resonance circuit 1.

### REFERENCE SIGNS LIST

1 antiresonant frequency-varying complex resonance circuit
2 reference terminal
3 input terminal
4 output terminal
5 power distribution circuit
6 power adder circuit
SG standard signal generator
Z0 impedance of standard signal generator
f frequency outputted by standard signal generator SG
7 first resonator circuit
8 second resonator circuit
9 first attenuation circuit
10 second attenuation circuit
11 first phase shift circuit
12 second phase shift circuit
100 first current path
200 second current path
z₁ load resistance
T11, T21, T31 terminal
T12, T22, T32 terminal
T13, T23, T33 terminal
T14, T24, T34 terminal
CNTR1, CNTR2 control terminal

1. An antiresonant frequency-varying complex resonance circuit, comprising:
a first current path on which a first phase shift and a first gain control are provided to an AC power signal being supplied;
at least one second current path on which a second phase shift and a second gain control are provided to the AC power signal, the second phase shift and the second gain control being different in amounts of shift and control from the first phase shift and the first gain control;
at least two resonant circuits which are provided each on the respective first and second current paths, and which have mutually different resonance points or antiresonance points for the AC power signals each passing through the respective first and second current paths and capture the respective AC power signals; and
an analog operational circuit for allowing the AC power signals having passed through the first current path and the second current path to be subjected to addition or subtraction in an analog fashion for output.

2. The antiresonant frequency-varying complex resonance circuit according to claim 1, wherein at least either the amount of the first and second phase shifts or the amount of the first and second gain controls is variable.

3. The antiresonant frequency-varying complex resonance circuit according to claim 1, wherein the at least two resonant circuits capture the respective AC power signals while the first or second phase shift and the first or second gain control are being provided.

4. The antiresonant frequency-varying complex resonance circuit according to claim 1, wherein the at least two resonant circuits are disposed most downstream of the first or second current path.

5. An antiresonant frequency-varying complex resonance circuit, comprising:
a first current path on which a phase shift and a gain control are provided to an AC power signal being supplied;
a second current path on which the AC power signal is relayed,
at least two resonant circuits which are provided each on the respective first and second current paths, and which have mutually different resonance points or antiresonance points for the AC power signals each passing through the respective first and second current paths and capture the respective AC power signals; and
an analog operational circuit for performing analog addition or subtraction on the AC power signals having passed through the first current path and the second current path for output.
